(19) United States
(12) Patent Application Publication
(10) Pub. No.: US 2021/0392253 A1
(43) Pub. Date: Dec. 16, 2021

(54) IMAGING ELEMENT AND IMAGING APPARATUS

(71) Applicant: SONY SEMICONDUCTOR SOLUTIONS CORPORATION, Kanagawa (JP)

(72) Inventors: Kiyotaka HORI, Kumamoto (JP); Daisuke CHINO, Kanagawa (JP)

(73) Assignee: SONY SEMICONDUCTOR SOLUTIONS CORPORATION, Kanagawa (JP)

(21) Appl. No.: 17/287,566

(22) PCT Filed: Sep. 3, 2019
(86) PCT No.: PCT/JP2019/034567

§ 371 Date: Apr. 22, 2021

(30) Foreign Application Priority Data
Oct. 29, 2018 (JP) 2018-202719

(51) Int. Cl. H04N 5/225

(52) U.S. Cl. CPC H04N 5/22521; H04N 5/357; H04N 5/2253

(57) ABSTRACT

To prevent a short circuit in an imaging element in which an electromagnetic shield is arranged. The imaging element is an imaging element including the electromagnetic shield and an adhesive. The electromagnetic shield is an electromagnetic shield that is arranged between a wiring and an imaging chip in a package that has the wiring inside and is provided with a recess for mounting the imaging chip. Furthermore, the adhesive is an adhesive used for mounting the imaging chip. Furthermore, the adhesive is arranged to cover the electromagnetic shield.

### TECHNICAL FIELD

The present disclosure relates to an imaging element and an imaging apparatus. More specifically, the present disclosure relates to an imaging element in which an imaging chip is mounted in a package, and an imaging apparatus including the imaging element.

### BACKGROUND ART

Conventionally, imaging apparatuses such as digital still cameras, digital video cameras (for example, camera-integrated recorders), and surveillance cameras that capture a subject and generate image data have become widespread. Furthermore, as an imaging element provided in these imaging apparatuses, for example, there is an imaging element in which wiring is provided inside a package on which an imaging chip is mounted. However, in recent years, since the specifications for flowing a large current have been increasing, it is important to prevent the characteristic deterioration of the imaging element due to the influence of magnetic field lines from the wiring provided inside the package.

Therefore, for example, there has been proposed an imaging element in which a shield for preventing the magnetic field lines generated in the wiring from reaching the imaging chip is arranged between the wiring provided inside the package and the imaging chip housed in a recess of the package (see, for example Patent Document 1).

### CITATION LIST

### Patent Document

Patent Document 1: WO 2017/081840 A

### SUMMARY OF THE INVENTION

### Problems to be Solved by the Invention

In the above-mentioned conventional technique, it is possible to prevent the magnetic field lines generated in the wiring provided inside the package from reaching the imaging chip. Here, a bonding wire, an inner lead, or the like that electrically connects the wiring provided inside the package to the imaging chip may be provided in the recess of the package. In this case, since the above-mentioned shield is a magnetic material or a conductor, it is important to prevent a short circuit between the shield and the inner lead or the like in the recess of the package.

The present disclosure has been made in view of the above-mentioned problems, and an object of the present disclosure is to prevent a short circuit in an imaging element in which a shield is arranged.

### Solutions to Problems

A first aspect of the present disclosure is an imaging element including: in a package having a wiring inside and provided with a recess for mounting an imaging chip, an electromagnetic shield that is arranged between the wiring and the imaging chip; and an adhesive that is used to mount the imaging chip, the adhesive being arranged to cover the electromagnetic shield.

Furthermore, in the first aspect, the adhesive may be arranged to cover the electromagnetic shield entirely.

Furthermore, in the first aspect, the adhesive may be arranged to cover an outer surface of the electromagnetic shield entirely.

Furthermore, in the first aspect, the electromagnetic shield may be formed by laminating an adhesive film on both surfaces of a metal film.

Furthermore, in the first aspect, the adhesive may be arranged to entirely cover the metal film exposed on an outer surface of the electromagnetic shield.

Furthermore, in the first aspect, the imaging chip may have a substantially rectangular shape in top view, the electromagnetic shield may have a substantially rectangular shape in top view, the adhesive may be arranged in a hollow-square shape in top view to cover an outer surface of the electromagnetic shield entirely, and the imaging chip may be mounted on an upper side of the adhesive arranged in the hollow-square shape.

Furthermore, in the first aspect, the electromagnetic shield may be formed by laminating an adhesive film on both surfaces of a metal film at a portion having a substantially rectangular shape in top view, and is provided with a cover end formed only by the adhesive film at a portion corresponding to one side of the substantially rectangular shape, and the adhesive may be arranged to entirely cover the metal film exposed on an outer surface of the electromagnetic shield.

Furthermore, in the first aspect, the imaging chip may have the substantially rectangular shape in top view, the adhesive may be arranged in a substantially hollow-square shape without a portion corresponding to the cover end in top view, and the imaging chip may be mounted on an upper side of the adhesive arranged in the substantially hollow-square shape.

Furthermore, in the first aspect, a size of the electromagnetic shield may be smaller than a size of the imaging chip in top view.

Furthermore, in the first aspect, a size of the electromagnetic shield may be substantially the same as a size of a light receiving surface of the imaging chip in top view.

Furthermore, in the first aspect, the metal film may include a soft magnetic material having a relative magnetic permeability of 1000 or more at 100 kHz.

Furthermore, in the first aspect, the metal film may have a relative magnetic permeability of 5000 or more at 100 kHz.

Furthermore, in the first aspect, the metal film may include copper or aluminum.

Furthermore, in the first aspect, the electromagnetic shield may include a magnetic shield or an electrostatic shield.

Furthermore, a second aspect of the present disclosure is an imaging apparatus including: an imaging element including, in a package having a wiring inside and provided with a recess for mounting an imaging chip, an electromagnetic shield that is arranged between the wiring and the imaging chip, and an adhesive that is used to mount the imaging chip, the adhesive being arranged to cover the electromagnetic shield; and a processing circuit that processes an image signal generated by the imaging element.

By adopting such aspects, an operation is provided in which the electromagnetic seal is covered with an adhesive in the recess of the package to prevent the occurrence of a short circuit between the electromagnetic shield and another conductor.

### BRIEF DESCRIPTION OF DRAWINGS

FIG. 1 is a cross-sectional view showing a configuration example of an imaging element 100 according to a first embodiment of the present disclosure.

FIG. 2 is a plan view showing a configuration example of the imaging element 100 according to the first embodiment of the present disclosure.

FIG. 3 is a diagram showing an example of a method for manufacturing an electromagnetic shield 140 according to the first embodiment of the present disclosure.

FIG. 4 is a diagram showing an example of a method for manufacturing the imaging element 100 according to the first embodiment of the present disclosure.

FIG. 5 is a cross-sectional view showing a configuration example of an imaging element 500 according to a comparative example.

FIG. 6 is a cross-sectional view showing a configuration example of an imaging element 200 according to a second embodiment of the present disclosure.

FIG. 7 is a plan view showing a configuration example of the imaging element 200 according to the second embodiment of the present disclosure.

FIG. 8 is a diagram showing an example of a method for manufacturing an electromagnetic shield 240 according to the second embodiment of the present disclosure.

FIG. 9 is a plan view and a cross-sectional view showing a configuration example of the electromagnetic shield 240 according to the second embodiment of the present disclosure.

FIG. 10 is a diagram showing an example of a method for manufacturing the imaging element 200 according to the second embodiment of the present disclosure.

FIG. 11 is a plan view showing a configuration example of an electromagnetic shield according to a variation example of the second embodiment of the present disclosure.

FIG. 12 is a block diagram showing a schematic configuration example of a camera, which is an example of the imaging apparatus to which the present disclosure can be applied.

### MODE FOR CARRYING OUT THE INVENTION

Next, modes for carrying out the present disclosure (hereinafter, referred to as embodiments) will be described with reference to the drawings. In the following drawings, the same or similar reference numerals are given to the same or similar parts. Furthermore, the embodiments will be described in the following order.

1. First Embodiment

2. Second Embodiment

3. Variation example

4. Application examples to cameras

### 1. First Embodiment

[Configuration of the Imaging Element]

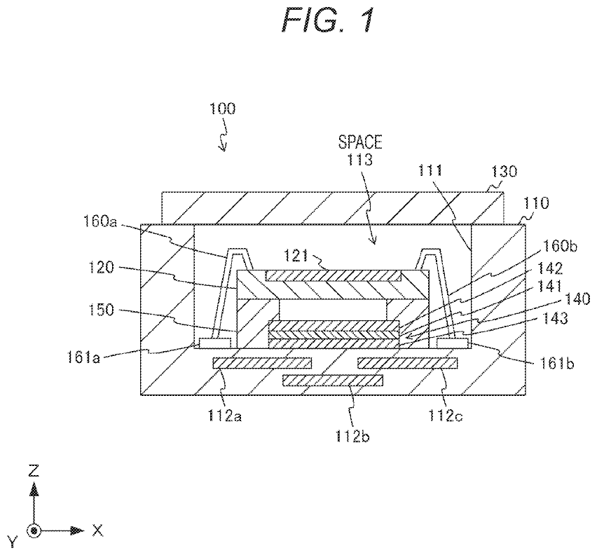

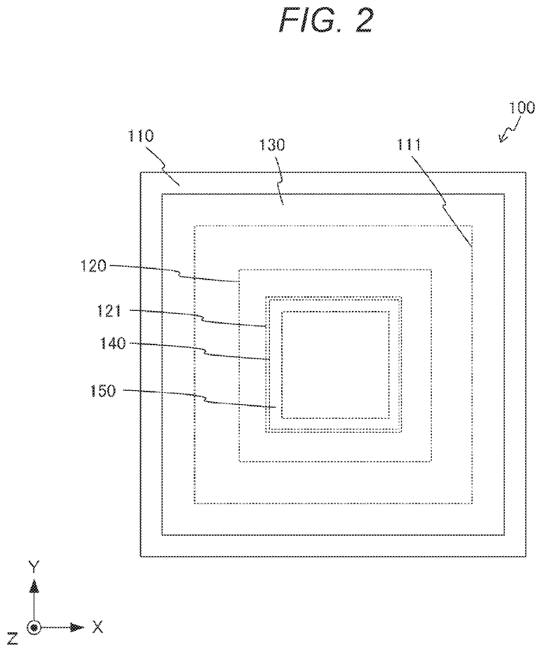

FIG. 1 is a cross-sectional view showing a configuration example of the imaging element 100 according to the first embodiment of the present disclosure. FIG. 2 is a plan view showing a configuration example of the imaging element 100 according to the first embodiment of the present disclosure. Note that in each of the following drawings, an X direction, a Y direction, and a Z direction are three directions orthogonal to each other.

The imaging element 100 includes a package 110, an imaging chip 120, a seal glass 130, an electromagnetic shield 140, a die bond resin 150, bonding wires 160a and 160b, and inner leads 161a and 161b.

The package 110 has a recess 111, and the imaging chip 120 is housed in the recess 111. The recess 111 is formed in the package 110 so as to be deeper than the thickness (distance in the Z direction) of the imaging chip 120 and the die bond resin 150. Note that as the material of the package 110, a material having an insulating property can be used. For example, a material such as synthetic resin or ceramic can be used as the material of the package 110.

Furthermore, the package 110 can be, for example, a stack-type package such as low temperature co-fired ceramics (LTCC) or high temperature co-fired ceramics (HTCC). Furthermore, package wirings 112a to 112c are provided inside the package 110. The package wirings 112a to 112c can be provided between the layers constituting the package 110.

The package wirings 112a to 112c electrically connect an external terminal (not shown) provided on the package 110 to the imaging chip 120. Furthermore, the package wirings 112a to 112c are electrically connected to the imaging chip 120 by, for example, the bonding wires 160a and 160b. Furthermore, the inner lead 161a to which the bonding wire 160a is connected and the inner lead 161b to which the bonding wire 160b is connected are formed in the recess 111 of the package 110. Note that as the material of the package wiring 112a to 112c, for example, tungsten, copper and the like can be used.

The imaging chip 120 is a semiconductor chip that receives light illuminated to a pixel region 121 (light receiving surface) via an optical system (not shown) and outputs an image signal according to the amount of light of the light received by each pixel. The imaging chip 120 includes, for example, a signal processing region and a circuit region arranged around the signal processing region. The signal processing region includes the pixel region 121 (light receiving surface) in which a plurality of photodiodes that converts light into an electrical signal is arranged one-dimensionally or two-dimensionally, an amplifier circuit, a memory, and the like arranged around the pixel region 121. Furthermore, the imaging chip 120 is mounted on the upper side (upper side in the Z direction) of the electromagnetic shield 140 adhered to a die attachment surface of the recess 111 of the package 110 by using the die bond resin 150. Note that as the imaging element, for example, a charge coupled device (CCD), a complementary metal oxide semiconductor (CMOS) sensor, or the like can be used.

The seal glass 130 is fixed to the package 110 so as to cover the pixel region 121 (light receiving surface) of the imaging chip 120, and hermetically seals a space 113 in which the imaging chip 120 is arranged. For example, the seal glass 130 is joined to the package 110 by an adhesive or the like to close the recess 111 of the package 110. Furthermore, the seal glass 130 has a light transmitting property and has a function of preventing scratches, dust and the like from adhering to the imaging chip 120.

As the material of the seal glass 130, for example, borosilicate glass, quartz glass, non-alkali glass, Pyrex (registered trademark) and the like can be used. Note that, instead of the seal glass 130, an infrared (IR) cut filter that blocks infrared light, a crystal low-pass filter, or the like may be used.

The electromagnetic shield 140 is an electromagnetic shield (magnetic shield or electrostatic shield) manufactured by laminating adhesive films 142 and 143 on both surfaces of the metal film 141, and is adhered to the die attachment surface of the recess 111 of the package 110. Furthermore, on the upper side (upper side in the Z direction) of the electromagnetic shield 140, the imaging chip 120 is mounted using the die bond resin 150. Here, noise (for example, band-shaped noise) can be generated due to magnetism from the package wirings 112a to 112c provided inside the package 110. Therefore, in the present disclosure, the electromagnetic shield 140 is arranged between the imaging chip 120 and the package wirings 112a to 112c (package 110). Therefore, noise (for example, band-shaped noise) generated by magnetism from the package wirings 112a to 112c can be suppressed, and deterioration of the characteristics of the imaging chip 120 can be prevented.

Furthermore, the size of the electromagnetic shield 140 is set to be smaller than the size of the imaging chip 120 in top view (in a case of being viewed from the upper side in the Z direction). That is, in the top view, the rectangular area of the electromagnetic shield 140 is set to be smaller than the rectangular area of the imaging chip 120. For example, as shown in FIG. 2, the size of the electromagnetic shield 140 can be substantially the same as the size of the pixel region 121 (the size smaller than the size of the imaging chip 120) in the top view.

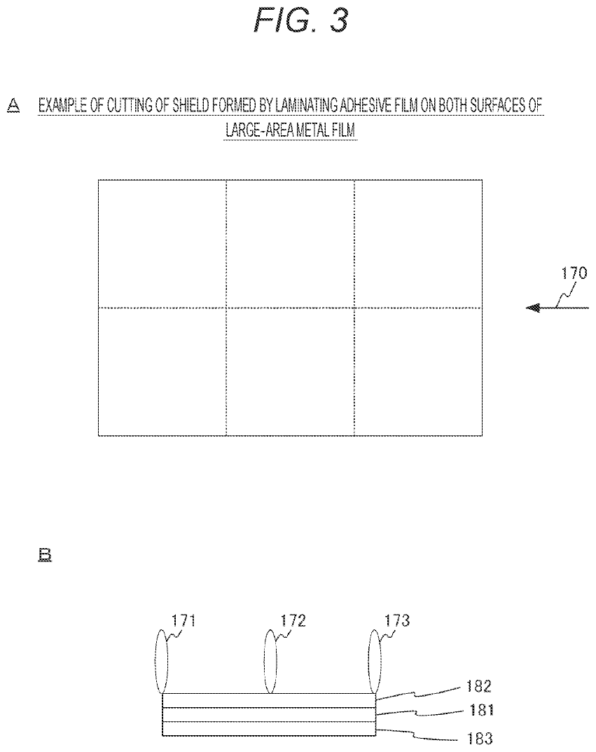

Note that the electromagnetic shield 140 can have a total thickness (thickness (distance in the Z direction)) of 100 um or less. Therefore, the height of the imaging chip 120 arranged on the die attachment surface can be reduced while maintaining the shielding effect. Furthermore, as the material of the metal film 141, a conductor such as a magnetic film, copper (for example, copper foil), or aluminum can be used. It is preferable to configure the metal film 141 from a material having high conductivity such as copper. This is because the electrostatic shielding effect of the electromagnetic shield 140 can be improved. Furthermore, for example, in a case where a soft magnetic material containing iron as a main component is used as the material of the metal film 141, the relative magnetic permeability at 100 kHz is preferably 1000 or more, and further, the relative magnetic permeability at 100 kHz is 5000 or more. This is because the magnetic shielding effect of the electromagnetic shield 140 can be improved. Note that the method for manufacturing the electromagnetic shield 140 will be described in detail with reference to FIG. 3.

The die bond resin 150 is an adhesive for die bonding used for mounting the imaging chip 120 in the recess 111 of the package 110. Specifically, the die bond resin 150 is used to mount the imaging chip 120 on the upper side (upper side in the Z direction) of the electromagnetic shield 140 adhered to the die attachment surface of the recess 111 of the package 110. Furthermore, the die bond resin 150 is applied so as to cover the side surface of the electromagnetic shield 140. That is, the die bond resin 150 is applied so as to cover (protect) the metal film 141 located on the side surface of the electromagnetic shield 140 with the die bond resin 150. In this way, the die bond resin 150 is arranged in a hollow-square shape so as to cover only the outer peripheral portion of the electromagnetic shield 140. Note that the die bond resin 150 is an example of the adhesive described in the claims.

[Manufacturing Example of the Electromagnetic Shield]

FIG. 3 is a diagram showing an example of a method for manufacturing the electromagnetic shield 140 according to the first embodiment of the present disclosure. FIG. 3A shows a top view of a large-area electromagnetic shield formed by laminating a large-area adhesive film on both surfaces of a large-area metal film. FIG. 3B shows a side view of the electromagnetic shield in a case where the large-area electromagnetic shield shown in FIG. 3A is cut by cutting members 171 to 173. Note that FIG. 3 shows an example of cutting a large-area electromagnetic shield into six electromagnetic shields for the sake of ease of description, but is not limited to this.

In FIG. 3A, dotted lines show a portion for cutting the large-area electromagnetic shield formed by laminating a large-area adhesive film on both surfaces of a large-area metal film.

FIG. 3B shows a side surface of the large-area electromagnetic shield when viewed from the direction of arrow 170 shown in FIG. 3A. As shown in FIG. 3B, the large-area electromagnetic shield is formed by laminating adhesive films 182 and 183 having the same (or substantially the same) size as the metal film 181 on both surfaces of the large-area metal film 181. Then, the electromagnetic shield 140 is manufactured by cutting the large-area electromagnetic shield formed by the large-area metal film 181 and the large-area adhesive films 182 and 183 to a desired size with the cutting members 171 to 173.

Here, for example, it is conceivable to sandwich both surfaces of a plurality of metal films that have been individually separated in advance with large-area adhesive films, and cut the adhesive films to be larger than the metal film to manufacture the electromagnetic shield. In this case, the side surface of the electromagnetic shield (the side surface of the metal film) can be protected by the large-cut adhesive film. However, in this case, it is considered that the productivity is low because it is necessary to perform processing such as sandwiching or cutting on the plurality of metal films that have been individually separated in advance.

On the other hand, in the first embodiment, the large-area electromagnetic shield formed by laminating the large-area adhesive films 182 and 183 on both surfaces of the large-area metal film 181 can be cut to manufacture the electromagnetic shield 140 used for the imaging element 100. Therefore, the productivity of the electromagnetic shield 140 can be increased, and the manufacturing cost of the imaging element 100 can be reduced.

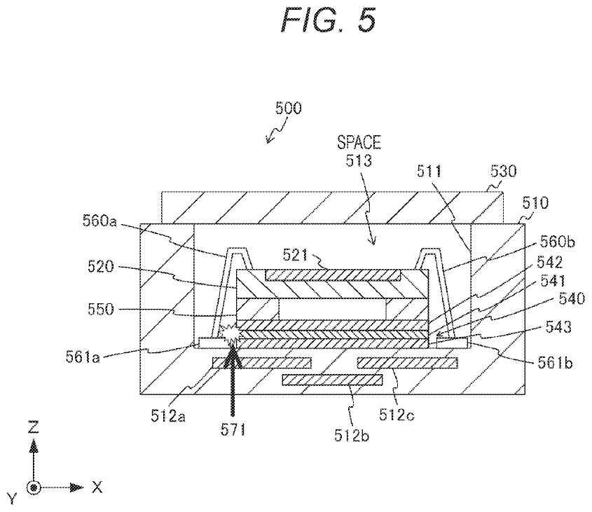

However, since the large-area electromagnetic shield is cut to manufacture the electromagnetic shield used for the imaging element, the metal film is exposed on the side surface of the electromagnetic shield. The influence of installing the imaging element with the metal film being exposed on the side surface of the electromagnetic shield will be described with reference to FIG. 5.

[Manufacturing Example of the Imaging Element]

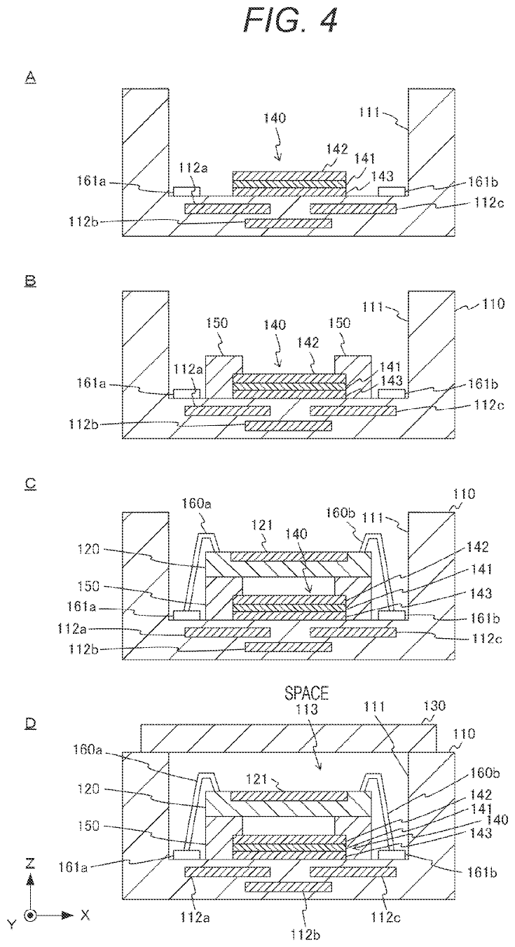

FIG. 4 is a diagram showing an example of a method for manufacturing the imaging element 100 according to the first embodiment of the present disclosure.

First, as shown in FIG. 4A, the electromagnetic shield 140 formed by laminating the adhesive films 142 and 143 on both surfaces of the metal film 141 is adhered to the die attachment surface of the recess 111 of the package 110.

Next, as shown in FIG. 4B, the die bond resin 150 is applied to cover the side surface of the outer peripheral portion (the surface where the metal film 141 is exposed) of the electromagnetic shield 140 adhered to the die attachment surface of the recess 111 of the package 110. That is, the die bond resin 150 is applied in a hollow-square shape so as to cover the side surface of the outer peripheral portion of the electromagnetic shield 140. Therefore, the metal film 141 located on the side surface of the electromagnetic shield 140 is protected by the die bond resin 150.

Next, as shown in FIG. 4C, the imaging chip 120 is placed on the die bond resin 150 applied to the side surface of the outer peripheral portion of the electromagnetic shield 140 adhered to the die attachment surface of the recess 111 of the package 110. After mounting the imaging chip 120, the die bond resin 150 is cured. Thereafter, wire bonding is performed, and the package wirings 112a to 112c of the package 110 and the imaging chip 120 are electrically connected by the bonding wires 160a and 160b.

Next, as shown in FIG. 4D, the space 113 in which the imaging chip 120 is arranged is hermetically sealed by fixing the seal glass 130 to the package 110.

[Effects of the Die Bond Resin]

The effects of the die bond resin 150 shown in FIGS. 1 and 2 will be described with reference to a comparative example.

FIG. 5 is a cross-sectional view showing a configuration example of an imaging element 500 according to the comparative example.

The imaging element 500 includes a package 510, an imaging chip 520, a seal glass 530, an electromagnetic shield 540, a die bond resin 550, bonding wires 560a and 560b, and inner leads 561a and 561b.

Note that each part of the imaging element 500 corresponds to each part of the same name of the imaging element 100 shown in FIG. 1. However, the die bond resin 150 in the imaging element 100 is applied so as to cover the side surface of the electromagnetic shield 140, whereas the die bond resin 550 in the imaging element 500 is applied onto the upper side of the electromagnetic shield 540. That is, the electromagnetic shield 540 is installed on the die attachment surface of the recess 511 of the package 510 with the metal film 541 on the side surface being exposed.

Here, it is assumed that the imaging element 500 is subjected to a high temperature and high humidity test. In this case, since the electromagnetic shield 540 is installed in the recess 511 of the package 510 with the metal film 541 being exposed on the side surface of the electromagnetic shield 540, the metal film 541 can elute in the high temperature and high humidity test. When the metal film 541 elutes in this way, as shown by arrow 571, a short circuit can occur between the eluted metal film 541 and the inner lead 561a of the package 510.

On the other hand, in the imaging element 100 shown in FIGS. 1 and 2, the side surface of the electromagnetic shield 140 is covered with the die bond resin 150 to protect the metal film 141. In this way, since the electromagnetic shield 140 is installed in the recess 111 of the package 110 with the metal film 141 on the side surface of the electromagnetic shield 140 being protected, it is possible to prevent the metal film 141 from being eluted by the high temperature and high humidity test. Therefore, it is possible to prevent the occurrence of a short circuit between the metal film 141 and the inner leads 161a and 161b of the package 110.

Note that, in the first embodiment, an example is shown in which the die bond resin 150 is arranged in a hollow-square shape so as to cover only the outer peripheral portion of the electromagnetic shield 140. However, the die bond resin 150 may be applied and arranged so as to cover the upper surface and all of the side surfaces of the electromagnetic shield 140.

As described above, with the imaging element 100 according to the first embodiment of the present disclosure, the side surface of the electromagnetic shield 140 arranged on the bottom surface of the imaging chip 120 is covered with an adhesive of the die bond resin 150 so that a short circuit between the electromagnetic shield 140 and the other conductors can be prevented.

### 2. Second Embodiment

In the first embodiment, an example is shown in which the die bond resin 150 is applied so as to cover the side surface of the electromagnetic shield 140 installed on the die attachment surface of the recess 111 of the package 110. In this way, in a case where the die bond resin 150 is applied in the form of a hollow-square, the space surrounded by the imaging chip 120, the die bond resin 150, and the electromagnetic shield 140 is sealed. Therefore, it is conceivable to provide an air hole in the space in consideration of increases in pressure in the space. Therefore, in the second embodiment, an example is shown in which a part of the hollow-square-shaped die bond resin is a slit and an air hole is provided in the space surrounded by the imaging chip, the die bond resin, and the electromagnetic shield.

[Configuration of the Imaging Element]

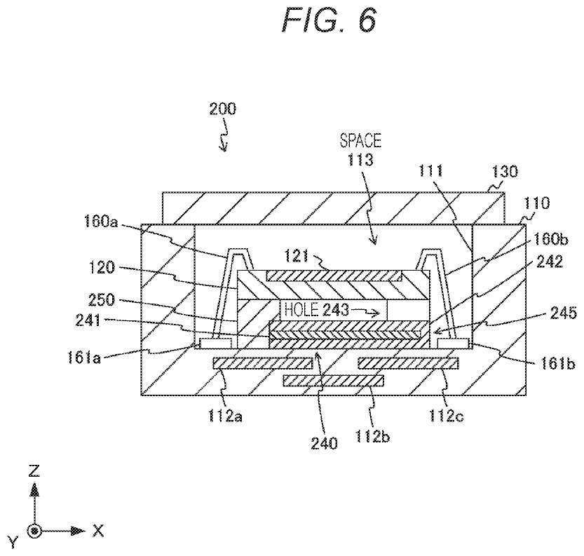

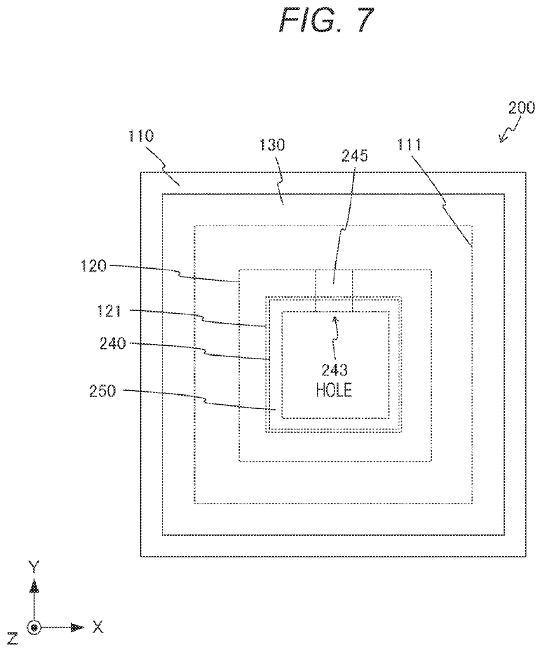

FIG. 6 is a cross-sectional view showing a configuration example of the imaging element 200 according to the second embodiment of the present disclosure. FIG. 7 is a plan view showing a configuration example of the imaging element 200 according to the second embodiment of the present disclosure.

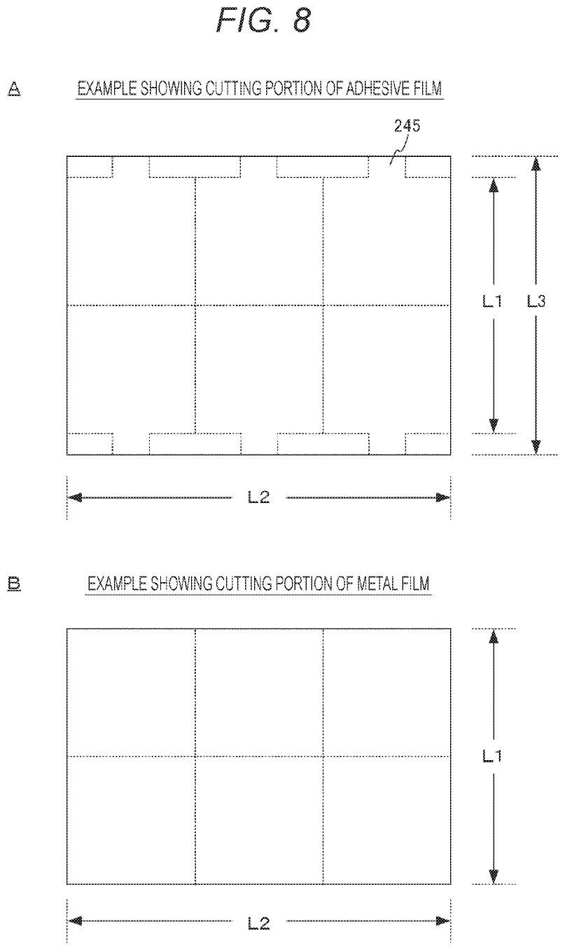

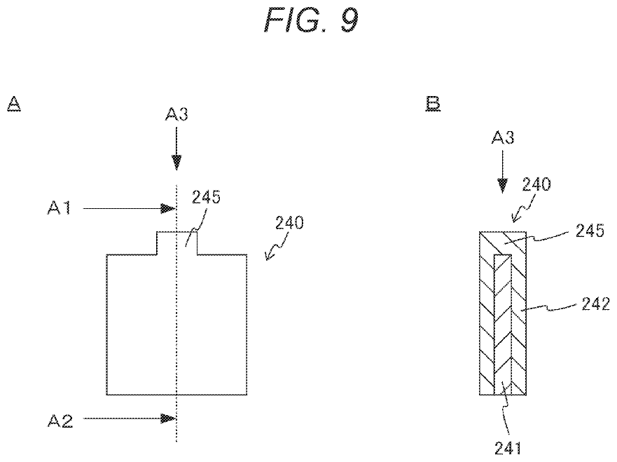

The imaging element 200 differs from the imaging element 100 in that an electromagnetic shield 240 having a cover end 245 is provided instead of the electromagnetic shield 140 in the imaging element 100 shown in FIGS. 1 and 2 and the die bond resin 250 is not applied to the portion corresponding to the cover end 245. Note that since the points other than the above are similar to the imaging element 100 shown in FIGS. 1 and 2, the parts common to the imaging element 100 are designated by the same reference numerals and the description thereof will be omitted. Furthermore, the cover end 245 will be described in detail with reference to FIGS. 8 and 9.

[Configuration Example of the Electromagnetic Shield]

FIG. 8 is a diagram showing an example of a method for manufacturing the electromagnetic shield 240 according to the second embodiment of the present disclosure. FIG. 9 is a plan view and a cross-sectional view showing a configuration example of the electromagnetic shield 240 according to the second embodiment of the present disclosure.

FIG. 8A shows a top view of a large-area adhesive film constituting a large-area electromagnetic shield. FIG. 8B shows a top view of a large-area metal film constituting a large-area electromagnetic shield. In FIGS. 8A and 8B, a portion for cutting the large-area adhesive film and the large-area metal film is shown by dotted lines. Note that FIG. 8 shows an example of cutting a large-area electromagnetic shield into six electromagnetic shields for the sake of ease of description, but is not limited to this.

As shown in FIG. 8B, the large-area metal film is manufactured in a roll shape (band shape) with its width L1 narrower than a width L3 of the large-area adhesive film. Note that a length L2 of the large-area metal film can be the same as (or substantially the same as) a length L2 of the large-area adhesive film.

Furthermore, as shown in FIG. 8A, the large-area adhesive film is cut so as to provide cover ends (portions without the metal film, protrusions) 245 at both ends (both ends in the width direction) of the roll (band).

In this way, in a case where the electromagnetic shield 240 having the cover ends 245 is manufactured, the large-area electromagnetic shield formed by laminating the large-area adhesive film shown in FIG. 8A on both surfaces of the large-area metal film shown in FIG. 8B is used. In other words, a roll-shaped one is used in which the left-right direction (left-right direction shown in FIG. 8) is significantly longer than the up-down direction (up-down direction shown in FIG. 8) and there is a peripheral portion (portion including the cover ends) without the metal film and only with the adhesive film at both ends in the up-down direction. Then, the peripheral portion is manufactured to correspond to one side of the electromagnetic shield 240, and the peripheral portion is cut out so as to have the shape of the cover ends 245.

FIG. 9 shows the electromagnetic shield 240 formed by the adhesive film cut so as to provide the cover ends 245 and the metal film cut so as not to provide the cover ends.

FIG. 9A shows a plan view of the electromagnetic shield 240 formed by laminating the adhesive film provided with the cover end 245 on both surfaces of the metal film not provided with the cover end. FIG. 9B shows a cross-sectional view of the electromagnetic shield 240 when viewed from the directions of arrows A1 and A2 of FIG. 9A.

As shown in FIG. 8, the adhesive film is provided with the cover end 245, but the metal film is not provided with the cover end. Therefore, as shown in FIG. 9B, the layer of the metal film 241 is not formed on the cover end 245, and the metal film 241 is not exposed on the side surface of the cover end 245 of the electromagnetic shield 240. As described above, a portion of the side surface of the metal film 241 of the electromagnetic shield 240 corresponding to the cover end 245 of the electromagnetic shield 240 is protected by the adhesive film 242 formed on both surfaces of the metal film 241. In particular, on the side surface at the tip of the cover end 245 of the electromagnetic shield 240 (the side surface indicated by arrow A3), the metal film 241 is not exposed and the side surface of the metal film 241 is protected by the adhesive film 242 forming the cover end 245.

As described above, regarding the cover end 245 of the electromagnetic shield 240, the side surface of the metal film 241 is protected by the adhesive film 242 forming the cover end 245 such that the metal film 241 is not exposed and does not need to be protected by the die bond resin 250. Therefore, in a case where the die bond resin 250 is applied to the side surface of the electromagnetic shield 240, the die bond resin 250 is not applied to the portion corresponding to the cover end 245 as shown in FIGS. 6 and 7. That is, the die bond resin 250 can be applied so that the cover end 245 becomes a slit of the die bond resin 250.

As described above, the die bond resin 250 is arranged in a hollow-square shape so as to cover only the outer peripheral portion (outer surface) of the electromagnetic shield 240, and a slit is formed at least one point of the hollow-square shape. Furthermore, the cover end 245 of the electromagnetic shield 240 is arranged in the slit. Furthermore, as shown in FIGS. 6 and 7, a hole 243 can be formed in the slit on the upper side (upper side in the Z direction) of the cover end 245.

[Manufacturing Example of the Imaging Element]

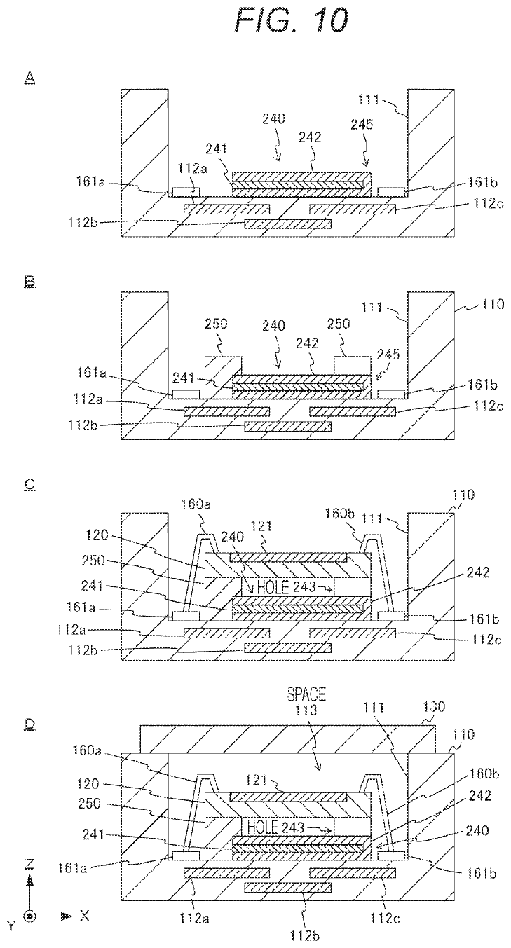

FIG. 10 is a diagram showing an example of a method for manufacturing the imaging element 200 according to the second embodiment of the present disclosure.

First, as shown in FIG. 10A, the electromagnetic shield 240 formed by laminating the adhesive film 242 on both surfaces of the metal film 241 is adhered to the die attachment surface of the recess 111 of the package 110. Note that, regarding the cover end 245 of the electromagnetic shield 240, the side surface of the metal film 241 is protected by the adhesive film 242 forming the cover end 245.

Next, as shown in FIG. 10B, the die bond resin 250 is applied to cover the side surface of the outer peripheral portion of the electromagnetic shield 240 (side surface other than the side surface of the tip of the cover end 245 of the electromagnetic shield 240) adhered to the die attachment surface of the recess 111 of the package 110. That is, the die bond resin 250 is applied in a hollow-square shape so as to cover the side surface of the outer peripheral portion of the electromagnetic shield 240, but the die bond resin 250 is absent only at the cover end 245 of the electromagnetic shield 240. That is, the die bond resin 250 is applied in a hollow-square shape so as to cover the side surface of the outer peripheral portion of the electromagnetic shield 240, and a slit is formed at least one point of the hollow-square shape (the position of the cover end 245 of the electromagnetic shield 240). By forming the slit at least one point of the die bond resin 250 applied in a hollow-square shape in this way, a hole 243 is formed on the upper side (upper side in the Z direction) of the cover end 245. Therefore, it is possible to prevent the space surrounded by the imaging chip 120, the die bond resin 250, and the electromagnetic shield 240 from being sealed. In a case where heating treatment is performed for curing the adhesive or the like, it is possible to prevent the imaging chip 120 from floating or being damaged due to an increase in pressure in the space.

As described above, the metal film 241 exposed on the side surface of the electromagnetic shield 240 is protected by the die bond resin 250. Furthermore, the cover end 245 of the electromagnetic shield 240 is arranged at the slit portion where the die bond resin 250 is absent, but the metal film 241 is not exposed on the side surface of the cover end 245. Furthermore, the metal film 241 in the vicinity of the cover end 245 of the electromagnetic shield 240 is protected by the adhesive film 242 forming the cover end 245.

Next, as shown in FIG. 10C, the imaging chip 120 is placed on the die bond resin 250 applied to the side surface of the outer peripheral portion of the electromagnetic shield 240 adhered to the die attachment surface of the recess 111 of the package 110. After the imaging chip 120 is placed, the die bond resin 250 is cured, and the package wirings 112a to 112c of the package 110 and the imaging chip 120 are electrically connected by the bonding wires 160a, 160b.

Next, as shown in FIG. 10D, the space 113 in which the imaging chip 120 is arranged is hermetically sealed by fixing the seal glass 130 to the package 110.

As described above, the imaging element 200 according to the second embodiment of the present disclosure can simplify the manufacturing process for the electromagnetic shield 240 by using the electromagnetic shield 240 including the clothing end 245. Furthermore, by omitting the die bond resin 250 on the clothing end 245, it is possible to prevent damage and the like to the imaging chip 120 in the manufacturing process for the imaging element 200.

### 3. Variation Examples

Although the example in which the shape of the cover end 245 of the above-mentioned electromagnetic shield 240 is rectangular (each side is smaller than one side of the electromagnetic shield 240), other shapes can be adopted for the cover end. Therefore, in the following, variation examples of the cover end provided on the electromagnetic shield will be shown.

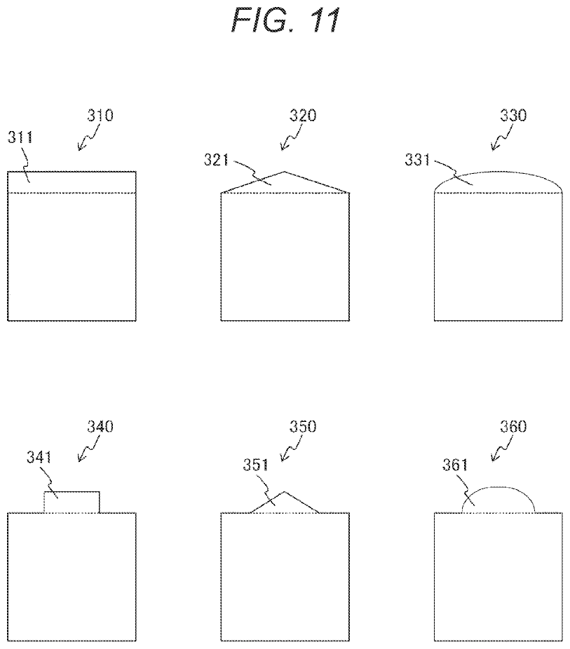

FIG. 11 is a plan view showing a configuration example of an electromagnetic shield according to a variation example of the second embodiment of the present disclosure.

Electromagnetic shields 310, 320, 330, 340, 350 and 360 are variations examples of the electromagnetic shield 240, and the shapes of the cover ends are different from that of the electromagnetic shield 240. Therefore, here, the shape of the cover end will be mainly described. Note that, in FIG. 11, the boundaries between the rectangular electromagnetic shields formed by laminating the adhesive film on both surfaces of the metal film and cover ends 311, 321, 331, 341, 351 and 361 formed only of the adhesive film are indicated by dotted lines.

The electromagnetic shield 310 is provided with a rectangular cover end 311 on one side of the rectangle of the electromagnetic shield 310 (a rectangle formed by laminating the adhesive film on both surfaces of the metal film). That is, in the electromagnetic shield 310, the whole of one side of the rectangle of the electromagnetic shield 310 is one rectangular cover end 311.

The electromagnetic shield 320 is provided with a triangular cover end 321 on one side of the rectangle of the electromagnetic shield 320 (a rectangle formed by laminating the adhesive film on both surfaces of the metal film). That is, in the electromagnetic shield 320, the whole of one side of the rectangle of the electromagnetic shield 320 is one triangular cover end 321.

The electromagnetic shield 330 is provided with an arc-shaped cover end 331 on one side of the rectangle of the electromagnetic shield 330 (a rectangle formed by laminating the adhesive film on both surfaces of the metal film). That is, in the electromagnetic shield 330, the whole of one side of the rectangle of the electromagnetic shield 330 is one arc-shaped cover end 331.

The electromagnetic shield 340 is provided with a rectangular cover end 341 on one side of the rectangle of the electromagnetic shield 340 (a rectangle formed by laminating the adhesive film on both surfaces of the metal film). That is, in the electromagnetic shield 340, the rectangular cover end 341 is provided on only a part of one side of the rectangle of the electromagnetic shield 340. Note that the electromagnetic shield 340 is obtained by changing only the length of the electromagnetic shield 240 shown in FIG. 9 in the left-right direction (left-right direction in FIG. 11).

The electromagnetic shield 350 is provided with a triangular cover end 351 on one side of the rectangle of the electromagnetic shield 350 (a rectangle formed by laminating the adhesive film on both surfaces of the metal film). That is, in the electromagnetic shield 350, the triangular cover end 351 is provided on only a part of one side of the rectangle of the electromagnetic shield 350.

The electromagnetic shield 360 is provided with an arc-shaped cover end 361 on one side of the rectangle of the electromagnetic shield 360 (a rectangle formed by laminating the adhesive film on both surfaces of the metal film). That is, in the electromagnetic shield 360, the arc-shaped cover end 361 is provided on only a part of one side of the rectangle of the electromagnetic shield 360.

### 4. Application Examples to Cameras

The technology according to the present disclosure (present technology) is applicable to a variety of products. For example, the present technology may be realized as an imaging element mounted in an imaging apparatus such as a camera.

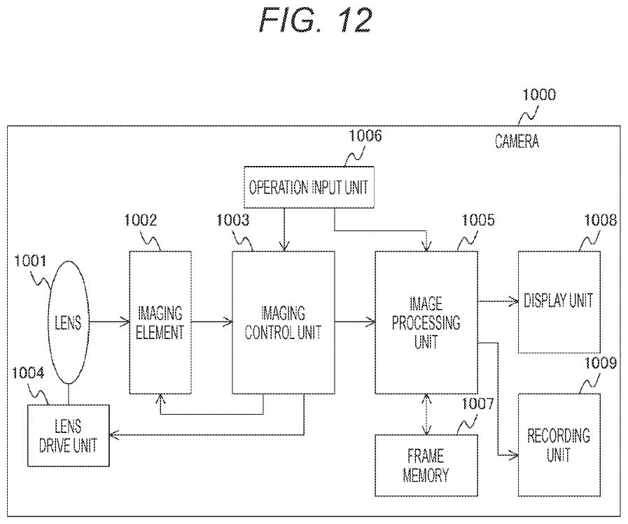

FIG. 12 is a block diagram showing a schematic configuration example of a camera, which is an example of the imaging apparatus to which the present technology can be applied. A camera 1000 in the drawing includes a lens 1001, an imaging element 1002, an imaging control unit 1003, a lens drive unit 1004, an image processing unit 1005, an operation input unit 1006, a frame memory 1007, a display unit 1008, and a recording unit 1009.

The lens 1001 is an imaging lens of the camera 1000. The lens 1001 collects light from a subject and makes it incident on the imaging element 1002 described later to form an image of the subject.

The imaging element 1002 is a semiconductor element that captures an image of the light from the subject collected by the lens 1001. The imaging element 1002 generates an analog image signal according to the illuminated light, converts it into a digital image signal, and outputs it.

The imaging control unit 1003 controls imaging by the imaging element 1002. The imaging control unit 1003 controls the imaging element 1002 by generating a control signal and outputting the control signal to the imaging element 1002. Furthermore, the imaging control unit 1003 can perform autofocus in the camera 1000 on the basis of the image signal output from the imaging element 1002. Here, the autofocus is a system that detects the focal position of the lens 1001 and automatically adjusts it. As this autofocus, a method for detecting an image plane phase difference using a phase difference pixel arranged in the imaging element 1002 and detecting the focal position (image plane phase difference autofocus) can be used. Furthermore, it is also possible to apply a method (contrast autofocus) of detecting the position where the contrast of the image is the highest as the focal position. The imaging control unit 1003 adjusts the position of the lens 1001 via the lens drive unit 1004 on the basis of the detected focal position, and performs autofocus. Note that the imaging control unit 1003 can be configured by, for example, a digital signal processor (DSP) equipped with firmware.

The lens drive unit 1004 drives the lens 1001 on the basis of the control of the imaging control unit 1003. The lens drive unit 1004 can drive the lens 1001 by changing the position of the lens 1001 using a built-in motor.

The image processing unit 1005 processes the image signal generated by the imaging element 1002. This processing corresponds to, for example, demosaicing for generating an image signal of a missing color among image signals corresponding to red, green, and blue for each pixel, noise reduction for removing noise of the image signal, encoding of the image signal, and the like. The image processing unit 1005 can be configured by, for example, a microcomputer equipped with firmware.

The operation input unit 1006 receives an operation input from the user of the camera 1000. As the operation input unit 1006, for example, a push button or a touch panel can be used. The operation input received by the operation input unit 1006 is transmitted to the imaging control unit 1003 or the image processing unit 1005. Thereafter, processing corresponding to the operation input, for example, processing such as imaging of the subject or the like is started.

The frame memory 1007 is a memory that stores a frame that is an image signal for one screen. The frame memory 1007 is controlled by the image processing unit 1005 and holds a frame in the process of image processing.

The display unit 1008 displays the image processed by the image processing unit 1005. A liquid crystal panel can be used for the display unit 1008, for example.

The recording unit 1009 records the image processed by the image processing unit 1005. For the recording unit 1009, for example, a memory card or a hard disk can be used.

The camera to which the present invention can be applied has been described above. The present technology can be applied to the imaging element 1002 among the configurations described above. Specifically, the imaging elements 100 and 200 described in FIGS. 1, 2, 6, 7 and the like can be applied to the imaging element 1002. By applying the imaging elements 100 and 200 to the imaging element 1002, the productivity of the electromagnetic shield included in the imaging element 1002 can be increased, and the manufacturing cost of the camera 1000 can be reduced. Furthermore, by applying the imaging elements 100 and 200 to the imaging element 1002, it is possible to prevent the occurrence of a short circuit in the recess of the package of the imaging element 1002. Note that the image processing unit 1005 is an example of the processing circuit described in the claims. The camera 1000 is an example of the imaging apparatus described in the claims.

Note that although the camera has been described as an example here, the technique according to the present invention may be applied to, for example, a monitoring apparatus.

Finally, the description of each embodiment described above is an example of the present disclosure, and the present disclosure is not limited to the above-described embodiments. Therefore, it goes without saying that various changes, even those different from the above-described embodiments, can be made according to the design and the like without departing from the technical concept according to the present disclosure.

Furthermore, the drawings in the above-described embodiment are schematic, and the ratios and the like of the dimensions of each part do not always match the actual one. Furthermore, it is needless to say that the drawings may include some parts having different dimensional relationships and ratios among the drawings.

Note that the present technology may be configured as below.

(1) An imaging element including:

in a package having a wiring inside and provided with a recess for mounting an imaging chip, an electromagnetic shield that is arranged between the wiring and the imaging chip; and

an adhesive that is used to mount the imaging chip, the adhesive being arranged to cover the electromagnetic shield.

(2) The imaging element according to (1), in which the adhesive is arranged to cover the electromagnetic shield entirely.

(3) The imaging element according to (1) or (2), in which the adhesive is arranged to cover an outer surface of the electromagnetic shield entirely.

(4) The imaging element according to any of (1) to (3), in which the electromagnetic shield is formed by laminating an adhesive film on both surfaces of a metal film.

(5) The imaging element according to (4), in which the adhesive is arranged to entirely cover the metal film exposed on an outer surface of the electromagnetic shield.

(6) The imaging element according to any of (1) to (5), in which

the imaging chip has a substantially rectangular shape in top view,

the electromagnetic shield has a substantially rectangular shape in top view,

the adhesive is arranged in a hollow-square shape in top view to cover an outer surface of the electromagnetic shield entirely, and

the imaging chip is mounted on an upper side of the adhesive arranged in the hollow-square shape.

(7) The imaging element according to any of (1) to (5), in which

the electromagnetic shield is formed by laminating an adhesive film on both surfaces of a metal film at a portion having a substantially rectangular shape in top view, and is provided with a cover end formed only by the adhesive film at a portion corresponding to one side of the substantially rectangular shape, and

the adhesive is arranged to entirely cover the metal film exposed on an outer surface of the electromagnetic shield.

(8) The imaging element according to (7), in which

the imaging chip has the substantially rectangular shape in top view,

the adhesive is arranged in a substantially hollow-square shape without a portion corresponding to the cover end in top view, and

the imaging chip is mounted on an upper side of the adhesive arranged in the substantially hollow-square shape.

(9) The imaging element according to any of (1) to (8), in which a size of the electromagnetic shield is smaller than a size of the imaging chip in top view.

(10) The imaging element according to any of (1) to (9), in which a size of the electromagnetic shield is substantially the same as a size of a light receiving surface of the imaging chip in top view.

(11) The imaging element according to (4) or (5), in which the metal film includes a soft magnetic material having a relative magnetic permeability of 1000 or more at 100 kHz.

(12) The imaging element according to (11), in which the metal film has a relative magnetic permeability of 5000 or more at 100 kHz.

(13) The imaging element according to any of (4), (5), (11) and (12), in which the metal film includes copper or aluminum.

(14) The imaging element according to any of (1) to (13), in which the electromagnetic shield includes a magnetic shield or an electrostatic shield.

(15) An imaging apparatus including:

an imaging element including, in a package having a wiring inside and provided with a recess for mounting an imaging chip, an electromagnetic shield that is arranged between the wiring and the imaging chip, and an adhesive that is used to mount the imaging chip, the adhesive being arranged to cover the electromagnetic shield; and

a processing circuit that processes an image signal generated by the imaging element.

### REFERENCE SIGNS LIST

100, 200, 500 Imaging element
110, 510 Package
111, 511 Recess
112a to 112c, 512a to 512c Package wiring
113, 513 Space
120, 520 Imaging chip
121, 521 Pixel region
130, 530 Seal glass
140, 240, 310, 320, 330, 340, 350, 360, 540 Electromagnetic shield
141, 241, 181, 541 Metal film
142, 143, 182, 183, 242, 542, 543 Adhesive film
150, 250, 550 Die bond resin
160a, 160b, 560a, 560b Bonding wire
161a, 161b, 561a, 561b Inner lead
243 Hole
245, 311, 321, 331, 341, 351, 361 Cover end
1000 Camera
1002 Imaging element
1005 Image processing unit

What is claimed is:

1. An imaging element comprising:
in a package having a wiring inside and provided with a recess for mounting an imaging chip, an electromagnetic shield that is arranged between the wiring and the imaging chip; and
an adhesive that is used to mount the imaging chip, the adhesive being arranged to cover the electromagnetic shield.

2. The imaging element according to claim 1, wherein the adhesive is arranged to cover the electromagnetic shield entirely.

3. The imaging element according to claim 1, wherein the adhesive is arranged to cover an outer surface of the electromagnetic shield entirely.

4. The imaging element according to claim 1, wherein the electromagnetic shield is formed by laminating an adhesive film on both surfaces of a metal film.

5. The imaging element according to claim 4, wherein the adhesive is arranged to entirely cover the metal film exposed on an outer surface of the electromagnetic shield.

6. The imaging element according to claim 1, wherein
the imaging chip has a substantially rectangular shape in top view,
the electromagnetic shield has a substantially rectangular shape in top view,
the adhesive is arranged in a hollow-square shape in top view to cover an outer surface of the electromagnetic shield entirely, and
the imaging chip is mounted on an upper side of the adhesive arranged in the hollow-square shape.

7. The imaging element according to claim 1, wherein
the electromagnetic shield is formed by laminating an adhesive film on both surfaces of a metal film at a portion having a substantially rectangular shape in top view, and is provided with a cover end formed only by the adhesive film at a portion corresponding to one side of the substantially rectangular shape, and
the adhesive is arranged to entirely cover the metal film exposed on an outer surface of the electromagnetic shield.

8. The imaging element according to claim 7, wherein
the imaging chip has a substantially rectangular shape in top view,
the adhesive is arranged in a substantially hollow-square shape without a portion corresponding to the cover end in top view, and
the imaging chip is mounted on an upper side of the adhesive arranged in the substantially hollow-square shape.

9. The imaging element according to claim 1, wherein a size of the electromagnetic shield is smaller than a size of the imaging chip in top view.

10. The imaging element according to claim 1, wherein a size of the electromagnetic shield is substantially same as a size of a light receiving surface of the imaging chip in top view.

11. The imaging element according to claim 4, wherein the metal film includes a soft magnetic material having a relative magnetic permeability of 1000 or more at 100 kHz.

12. The imaging element according to claim 11, wherein the metal film has a relative magnetic permeability of 5000 or more at 100 kHz.

13. The imaging element according to claim 4, wherein the metal film includes copper or aluminum.

14. The imaging element according to claim 1, wherein the electromagnetic shield includes a magnetic shield or an electrostatic shield.

15. An imaging apparatus comprising:
an imaging element including, in a package having a wiring inside and provided with a recess for mounting an imaging chip, an electromagnetic shield that is arranged between the wiring and the imaging chip, and an adhesive that is used to mount the imaging chip, the adhesive being arranged to cover the electromagnetic shield; and
a processing circuit that processes an image signal generated by the imaging element.
